(19) United States
(12) Patent Application Publication
(10) Pub. No.: US 2011/0175086 A1
(43) Pub. Date: Jul. 21, 2011

(54) PHOTODIODE, MANUFACTURING METHOD FOR THE SAME, AND DISPLAY DEVICE INCLUDING PHOTODIODE

(75) Inventors: Hiromi Katoh, Osaka-shi (JP); Christopher Brown, Oxford (GB); Tomohiro Kimura, Osaka-shi (JP)

(73) Assignee: SHARP KABUSHIKI KAISHA, Osaka-shi, Osaka (JP)

(21) Appl. No.: 13/120,427

(22) PCT Filed: May 14, 2009
(86) PCT No.: PCT/JP2009/058985

§ 371 Date: Mar. 23, 2011

(30) Foreign Application Priority Data
Sep. 29, 2008 (JP) 2008-251114

(51) Int. Cl. H01L 31/0376; H01L 31/20

(52) U.S. Cl. 257/53; 438/87; 257/E31.048

(57) ABSTRACT

A photodiode (7) formed in a polycrystalline silicon layer or a continuous grain silicon layer on a base substrate (5) of a display device includes a semiconductor region of a first conductivity-type (n layer (21)), an intrinsic semiconductor region (i layer (22)), and a semiconductor region of a second conductivity-type (p layer (23)) that is opposite from the first conductivity-type. At least a portion of the intrinsic semiconductor region (i layer (22)) is amorphous silicon.

### TECHNICAL FIELD

The present invention relates to a photodiode provided in a display device, a manufacturing method for the same, and a display device including a photodiode.

### BACKGROUND ART

Conventionally, there has been proposed a display device with a photosensor that, due to including a photodetection element such as a photodiode inside a pixel, can detect the brightness of external light and pick up an image of an object that has come close to the display. Such a display device with a photosensor is envisioned to be used as a bidirectional communication display device, a display device with a touch panel function, or a display device with a scanner function.

In a conventional display device with a photosensor, when using a semiconductor process to form known constituent elements such as signal lines, scan lines, TFTs (Thin Film Transistor), and pixel electrodes on an active matrix substrate, a photodiode and the like are formed on the active matrix substrate at the same time (e.g., see PTL 1). PIN diodes having a lateral structure are used as the photodiodes. The PIN diodes are formed by providing a p layer, an i layer, and an n layer in the stated order in a silicon film used also for the TFTs, with use of the process for forming the TFTs.

With the liquid crystal display device disclosed in the aforementioned PTL 1, the photodiodes are formed in a matrix on the active matrix substrate, and thus the liquid crystal display panel functions as an area sensor.

### CITATION LIST

### Patent Literature

PTL 1: JP 2006-3857A

### DISCLOSURE OF INVENTION

### Problem to be Solved by the Invention

However, in the case of using photodiodes as photosensors as described above, the wavelength dependency of the photodiodes is a problem. Specifically, the sensitivity of the photodiodes is dependent on the wavelength of light that is received, and the sensitivity decreases as the wavelength band becomes higher. Thus there is the problem that, for example, red light cannot be detected with favorable sensitivity.

An object of the present invention is to solve the above-described problem, and to provide a photodiode having photodetection sensitivity close to human luminosity function in the wavelength band of visual light and a display device with a photosensor that uses this photodiode.

### Means for Solving Problem

In order to achieve the above-described object, a photodiode according to the present invention is a photodiode formed in a polycrystalline silicon layer or a continuous grain silicon layer on a substrate of a display device, the photodiode including: a semiconductor region of a first conductivity-type, an intrinsic semiconductor region, and a semiconductor region of a second conductivity-type that is opposite from the first conductivity-type, wherein at least a portion of the intrinsic semiconductor region is amorphous silicon.

A display device according to the present invention includes the above-described photodiode.

Also, a manufacturing method for a photodiode according to the present invention includes the steps of forming a polycrystalline silicon layer or a continuous grain silicon layer on a substrate of a display device; causing amorphization of at least a portion of a region to be an intrinsic semiconductor region of the photodiode in the silicon layer by ion implantation; and forming a semiconductor region of a first conductivity-type of the photodiode, and a semiconductor region of a second conductivity-type that is opposite from the first conductivity-type, in the silicon layer.

### Effects of the Invention

The present invention enables providing a photodiode having photodetection sensitivity close to human luminosity function in the wavelength band of visible light and a display device using the same.

### BRIEF DESCRIPTION OF DRAWINGS

FIG. 1 is a cross-sectional diagram schematically showing an overall configuration of a liquid crystal display device according to an embodiment of the present invention.

FIG. 2 is a cross-sectional diagram showing an enlarged view of part of an active matrix substrate of the liquid crystal display device shown in FIG. 1.

FIG. 3 is a graph showing a comparison of the light absorption efficiency of a photodiode 7 according to the embodiment of the present invention and a conventional photodiode in which the entirety of the i layer is formed from continuous grain silicon.

FIGS. 4(a) to 4(d) show a series of main manufacturing steps in the initial stage of the manufacture of an active matrix substrate.

FIGS. 5(a) to 5(g) are plan views showing examples of mask patterns used in the amorphization of at least part of an i layer by ion implantation.

FIGS. 6(a) to 6(c) show a series of main active matrix substrate manufacturing steps implemented after the step shown in FIG. 4(d).

FIGS. 7(a) to 7(c) show a series of active matrix substrate manufacturing steps implemented after the step shown in FIG. 6(c).

### DESCRIPTION OF THE INVENTION

A photodiode according to an embodiment of the present invention is a photodiode formed in a polycrystalline silicon layer or a continuous grain silicon layer on a substrate of a display device, the photodiode including: a semiconductor region of a first conductivity-type, an intrinsic semiconductor region, and a semiconductor region of a second conductivity-type that is opposite from the first conductivity-type, wherein at least a portion of the intrinsic semiconductor region is amorphous silicon.

In the case where the intrinsic semiconductor region to be the portion for receiving light in the photodiode is formed from amorphous silicon, the absorption coefficient curve exhibits wavelength dependency similar to that of the human luminosity function curve. In other words, according to the configuration of the above-described embodiment of the present invention, it is possible to realize a photodiode whose sensitivity to the wavelengths of incident light is closer to that of the human eye, compared to a conventional photodiode in which the entirety of the photodiode is formed from polycrystalline silicon or continuous grain silicon.

The photodiode according to this embodiment may have any of the following configurations: (1) the entirety of the intrinsic semiconductor region, as well as the first conductivity-type semiconductor region and the second conductivity-type semiconductor region are amorphous silicon; (2) the entirety of the intrinsic semiconductor region, a junction portion of the intrinsic semiconductor region and the first conductivity-type semiconductor region, and a junction portion of the intrinsic semiconductor region and the second conductivity-type semiconductor region are amorphous silicon; (3) in the intrinsic semiconductor region, a region excluding at least one of a junction portion with the first conductivity-type semiconductor region, and a junction portion with the second conductivity-type semiconductor region is amorphous silicon.

Also, a display device including the photodiode having the above-described configuration is also an embodiment of the present invention. In this display device, a configuration is possible in which the substrate is an active matrix substrate having a plurality of active elements arranged in a matrix, and a plurality of the photodiodes are formed on the active matrix substrate.

Also, a manufacturing method for a photodiode according to an embodiment of the present invention includes the steps of forming a polycrystalline silicon layer or a continuous grain silicon layer on a substrate of a display device; causing amorphization of at least a portion of a region to be an intrinsic semiconductor region of the photodiode in the silicon layer by ion implantation; and forming a semiconductor region of a first conductivity-type of the photodiode, and a semiconductor region of a second conductivity-type that is opposite from the first conductivity-type, in the silicon layer.

Argon ions or silicon ions can be used in the ion implantation step.

Also, in the ion implantation step, ion implantation may be performed on the entirety of the region to be the intrinsic semiconductor region, as well as on a region to be the first conductivity-type semiconductor region and a region to be the second conductivity-type semiconductor region, in the silicon layer.

Alternatively, in the ion implantation step, ion implantation may be performed on the entirety of the region to be the intrinsic semiconductor region, a region to be a junction portion of the intrinsic semiconductor region and the first conductivity-type semiconductor region, and a region to be a junction portion of the intrinsic semiconductor region and the second conductivity-type semiconductor region, in the silicon layer.

Furthermore, in the ion implantation step, ion implantation may be performed on, within the region to be the intrinsic semiconductor region, a region excluding at least one of a region to be a junction portion with the first conductivity-type semiconductor region, and a region to be a junction portion with the second conductivity-type semiconductor region, in the silicon layer.

Below is a description of a more specific embodiment of the present invention with reference to the drawings. Note that although the below embodiment shows an example of a configuration in the case where a display device according to the present invention is implemented as a liquid crystal display device, the display device according to the present invention is not limited to a liquid crystal display device, and is applicable to an arbitrary display device in which an active matrix substrate is used. It should also be noted that due to having photosensors, the display device according to the present invention is envisioned to be used as a display device with a touch panel function in which an input operation is performed by detecting an object that has come close to the screen, or a bidirectional communication display device equipped with a display function and an imaging function. The display device according to the present invention is also envisioned to be used as a display device that, for example, detects the brightness of ambient light with use of the photosensors, and controls the display brightness according to the ambient brightness.

Also, for the sake of convenience in the description, the drawings that are referred to below show simplifications of, among the constituent members of the embodiment of the present invention, only relevant members that are necessary for describing the present invention. Accordingly, the display device according to the present invention may include arbitrary constituent members that are not shown in the drawings referred to in this specification. Also, regarding the dimensions of the members in the drawings, the dimensions of the actual constituent members, the ratios of the dimensions of the members, and the like are not shown faithfully.

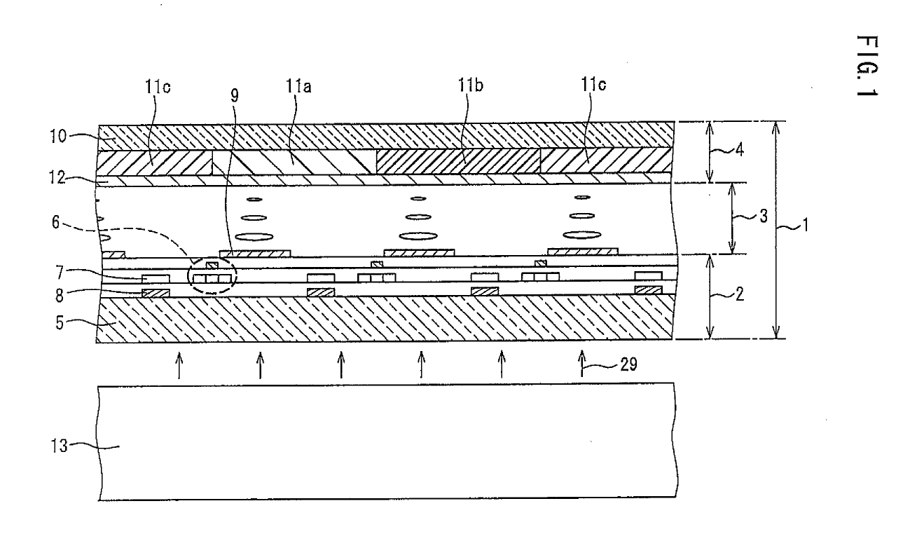

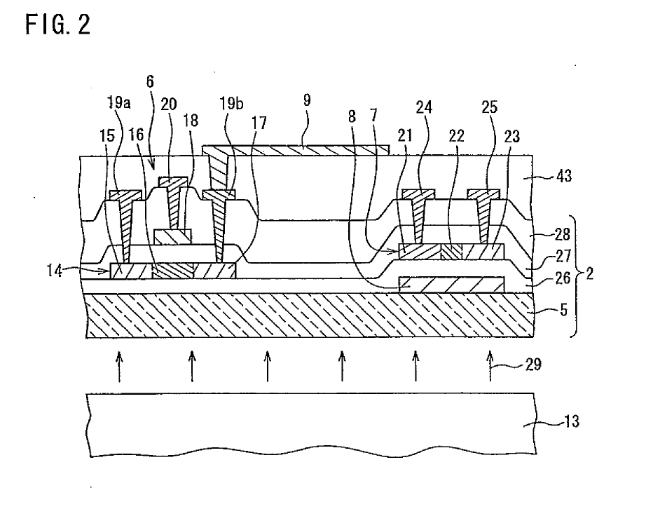

FIG. 1 is a cross-sectional diagram schematically showing an overall configuration of a liquid crystal display device according to an embodiment of the present invention. FIG. 2 is a cross-sectional diagram showing an enlarged view of part of an active matrix substrate of the liquid crystal display device shown in FIG. 1.

As shown in FIG. 1, the liquid crystal display device according to the present embodiment includes a liquid crystal display panel 1 and a backlight 13 that illuminates the liquid crystal display panel 1. The liquid crystal display panel 1 includes an active matrix substrate 2, a liquid crystal layer 3, and a filter substrate 4, and has a configuration in which the liquid crystal layer 3 is sandwiched between the active matrix substrate 2 and the filter substrate 4.

As shown in FIG. 1, the active matrix substrate 2 includes a plurality of active elements 6 and pixel electrodes 9 that are arranged in a matrix on a glass substrate 5, which is to be the base substrate. Each pixel is configured by a set of an active element 6 and a pixel electrode 9. In the present embodiment, the active elements 6 are TFTs (Thin Film Transistors). Note that hereinafter, the active elements are noted as TFTs 6 in the description.

The filter substrate 4 has a configuration in which a color filter and a common electrode 12 are provided on a glass substrate 10, which is to be the base substrate. The color filter is configured by a red color layer 11a, a green color layer 11b, and a blue color layer 11c that are each in correspondence with any one of the pixels.

As shown in FIG. 2, each of the TFTs 6 includes a silicon film 14 and a gate electrode 18. The silicon film 14 is formed on a first interlayer insulating film 26 that covers the top face of the glass substrate 5. The gate electrode 18 is formed on a second interlayer insulating film 27 that covers the silicon film 14, and a portion where the second interlayer insulating film 27 and the gate electrode 18 overlap functions as a gate insulating film. Also, the gate electrode 18 is covered by a third interlayer insulating film 28. In the present embodiment, the silicon film 14 is formed from continuous grain silicon (CGS), which is superior in terms of charge transfer rate.

Formed in the silicon film 14 are an n-type diffusion layer, which is to be a source region 15, and an n-type diffusion layer, which is to be a drain region 17. The region of the silicon film 14 directly below the gate electrode 18, that is to say, the region between the source region 16 and the drain region 17 is a channel region 16. Furthermore, source wiring 19a that penetrates the second interlayer insulating film 27 and the third interlayer insulating film 28 is connected to the source region 15, and drain wiring 19b that penetrates the second interlayer insulating film 27 and the third interlayer insulating film 28 is connected to the drain region 17. Gate wiring 20 that penetrates the third interlayer insulating film 28 is connected to the gate electrode 18.

Furthermore, an insulating protective film 43 is formed so as to cover the third interlayer insulating film, the source wiring 19a, the drain wiring 19b, and the gate wiring 20. Also, a pixel electrode 9 formed from ITO or the like is formed on the protective film 43. In the present embodiment, the pixel electrode 9 is electrically connected to the drain wiring 19b by a conduction passage that penetrates the protective film 43.

Furthermore, as shown in FIGS. 1 and 2, the active matrix substrate 2 of the present embodiment includes photodiodes 7 and light shielding films 8 that shield the photodiodes 7 from illumination light 29 from the backlight 13. The photodiodes 7 and the light shielding films 8 are provided in a matrix. Note that one photodiode 7 and one light shielding film 8 are provided for each pixel or for a plurality of pixels, and the area sensor is configured by the plurality of photodiodes 7.

As shown in FIG. 2, each of the photodiodes 7 is formed by a silicon film that is provided on the first interlayer insulating film 26. The photodiode 7 is a PIN diode having a lateral structure, and includes a p-type semiconductor region (p layer) 21, an intrinsic semiconductor region (i layer) 22, and an n-type semiconductor region (n layer) 23 arranged in the stated order along the surface direction.

Note that in the present embodiment, the i layer 22 needs only be a region that is nearly electrically neutral in comparison with the adjacent p layer 21 and n layer 23. The i layer 22 is preferably a region that includes no impurities whatsoever, or a region whose conduction electron density and hole density are equivalent. Also, in FIG. 2, 24 indicates wiring connected to the p layer 21, and 25 indicates wiring connected to the n layer 22. The wiring 24 and the wiring 25 are also covered by the protective film 43.

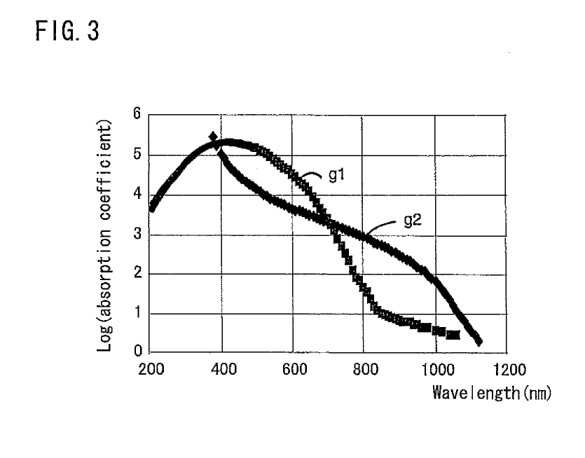

At least part of the i layer 22 of the photodiode 7 is formed from amorphous silicon. Accordingly, the photodiode 7 has a superior advantage in that sensitivity to visible light is improved. FIG. 3 is a graph showing a comparison of the light absorption efficiency of the photodiode 7 according to the present embodiment and a conventional photodiode in which the entirety of the i layer is formed from continuous grain silicon. In FIG. 3, g1 indicates a characteristic curve of the photodiode 7 according to the present embodiment, and g2 indicates a characteristic curve of the conventional photodiode. As can be seen in FIG. 3, the photodiode 7 according to the present embodiment has a higher absorption coefficient than the conventional photodiode throughout the entire wavelength range of visible light (approximately 400 to 700 nm). Note that the characteristic curves shown in FIG. 3 are merely examples. The characteristics of photodiodes change depending on processing conditions such as the thickness of the silicon film. Accordingly, FIG. 3 is not intended to limit the characteristics of the photodiode according to the embodiment of the present invention.

As described above, due to at least part of the i layer 22 being formed from amorphous silicon, the light absorption coefficient of the i layer 22 with respect to the wavelength range of visible light can be improved compared to a photodiode in which the entirety of the i layer is formed from continuous grain silicon, thus obtaining the effect of an increase in photocurrent. This enables detecting red light with favorable sensitivity, and realizing a photosensor with high sensitivity to visible light.

Furthermore, the variation characteristics of the wavelength absorption coefficient of amorphous silicon is substantially the same as the luminosity function curve. Specifically, the absorption coefficient of amorphous silicon has a peak at the wavelength to which the human eye is most sensitive (in the vicinity of 555 nm). Accordingly, forming at least part of the i layer 22 in the photodiode 7 from amorphous silicon enables realizing a photosensor having sensitivity characteristics close to those of the human eye.

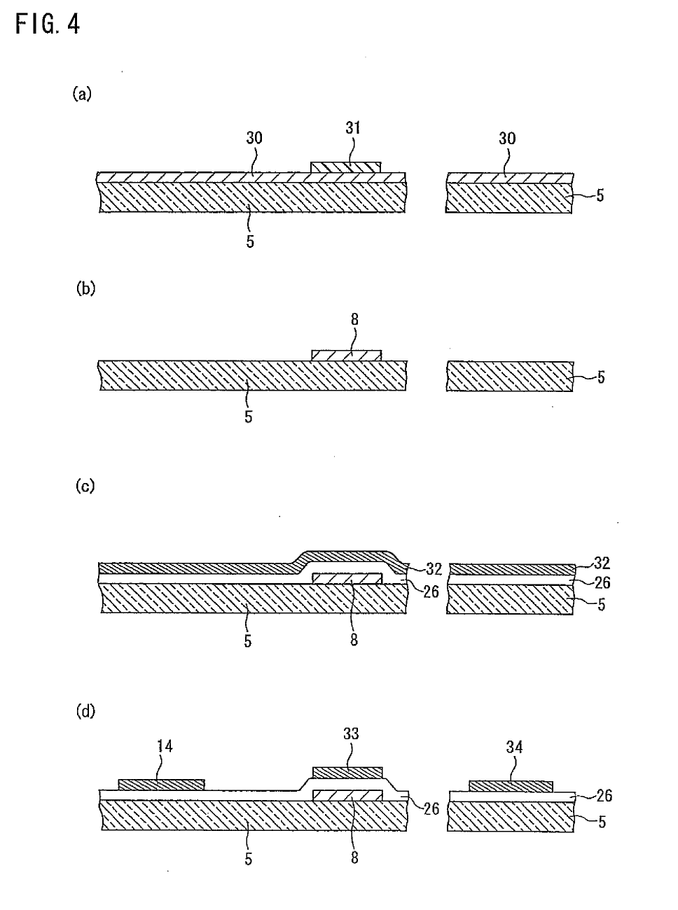

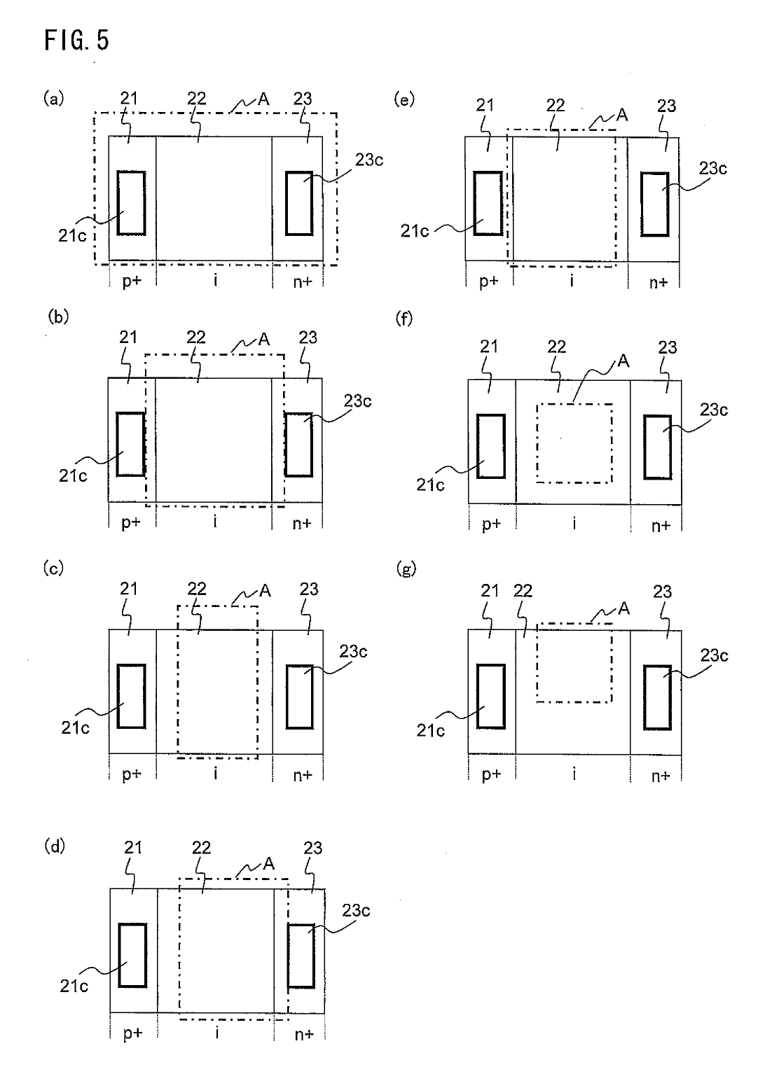

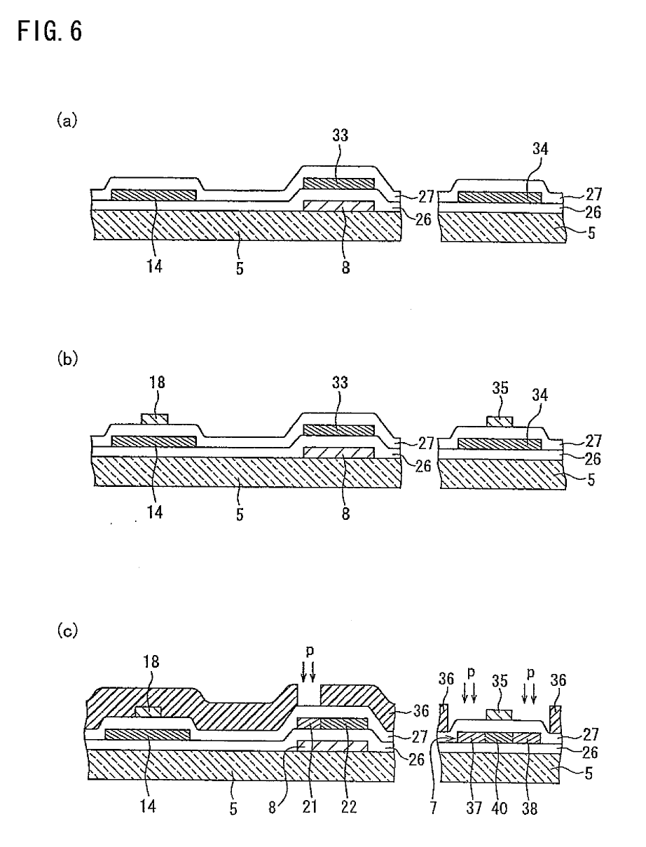

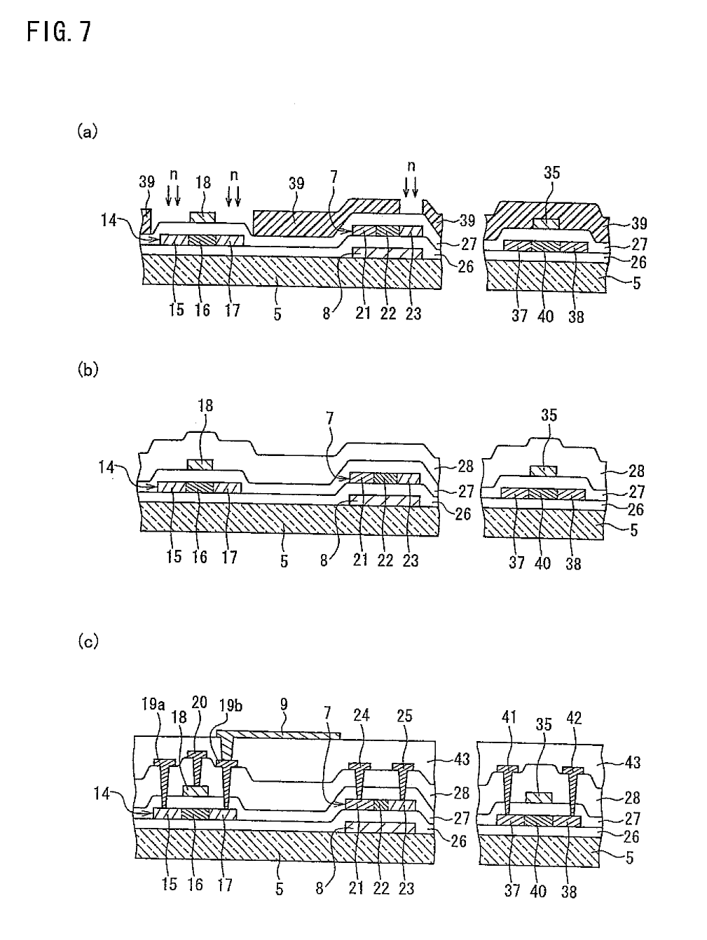

Next is a description of manufacturing steps for the liquid crystal display device of the present embodiment with reference to FIGS. 4 to 7. FIGS. 4 to 7 are cross-sectional diagrams showing main manufacturing steps for the liquid crystal display device of the present embodiment. FIGS. 4(a) to 4(d) show a series of main manufacturing steps in the initial stage of the manufacture of the active matrix substrate. FIGS. 5(a) to 5(g) are plan views showing examples of mask patterns used in the amorphization of at least part of the i layer 22 by ion implantation. FIGS. 6(a) to 6(c) show a series of main active matrix substrate manufacturing steps implemented after the step shown in FIG. 4(d). FIGS. 7(a) to 7(c) show a series of active matrix substrate manufacturing steps implemented after the step shown in FIG. 6(c).

FIGS. 4, 6, and 7 also show a TFT configuring a pixel and a photodiode, and additionally a TFT configuring a peripheral circuit. Cross-hatching of insulating materials has been omitted in FIG. 4, 6, or 7.

As shown in FIG. 4(a), firstly a silicon film 30 that is to be the light shielding film 8 is formed on one surface of the glass substrate 5 that is to be the base substrate of the active matrix substrate (see FIGS. 1 and 2) by a CVD (Chemical Vapor Deposition) method, a sputtering method, or the like. As described above, the silicon film 30 is formed from amorphous silicon. Also, the film thickness needs only be, for example, 50 nm or more, and is set to 200 nm in the examples in FIGS. 4, 6, and 7. Then, as shown in FIG. 4(a), a resist pattern 31 is formed by a photolithography method on a portion of the silicon film 30 that overlaps a light shielding film 8 formation region.

Next, as shown in FIG. 4(b), the amorphous silicon film 30 is etched using the resist pattern 31 as a mask, thus obtaining the light shielding film 8. Then, as shown in FIG. 4(c), the first interlayer insulating film 26 is formed such that the light shielding film 8 is covered. The first interlayer insulating film 26 can be formed by, for example, forming a silicon oxide film or silicon nitride film by a CVD method. Also, the first interlayer insulating film 26 may be a single-layer or multi-layer film. The thickness is set to, for example, 100 nm to 500 nm.

Furthermore, as shown in FIG. 4(c), a silicon film 32 that is to be a TFT and a photodiode is formed on the first interlayer insulating film 26 by a CVD method or the like. As described above, the silicon film 32 is formed from continuous grain silicon. Specifically, the silicon film 32 is formed through the following steps.

Firstly, a silicon oxide film and an amorphous silicon film are formed in the stated order on the first interlayer insulating film 26. Next, nickel, which is to be a catalyst for promoting crystallization, is added to the surface layer of the amorphous silicon film. Next, a reaction between the nickel and the amorphous silicon film is caused by anneal processing, thus obtaining the silicon film 32 formed by continuous grain silicon.

Next, a resist pattern (not shown) is formed on a portion of the silicon film 32 that overlaps with the TFT (including the TFT of both the pixel and the peripheral circuit) formation region and the photodiode formation region, and etching is performed using this resist pattern as a mask. Accordingly, as shown in FIG. 4(d), the silicon film 14 configuring the pixel driving TFT 6 (see FIGS. 1 and 2), a silicon film 33 configuring the photodiode 7, and a silicon film 34 configuring the peripheral circuit TFT are obtained.

After the patterning of the silicon films 14, 33, and 34, resist patterning is performed so as to open a region where amorphization is necessary in the silicon film 33 forming the photodiode 7, and open a region other than the photodiode 7 formation region where amorphization is necessary. Then, with use of this resist as a mask, ion implantation for amorphizing the silicon films is performed. As merely one example, it is sufficient to implant Ar ions using an accelerating voltage (implantation energy) of approximately 40 [keV] and a dose amount of 1×10¹⁵ [ions].

The following describes an example of mask patterns used when amorphizing at least part of the silicon film 33 forming the photodiode 7 by ion implantation, with reference to FIGS. 5(a) to 5(g). Note that the rectangular regions A shown by dashed-dotted lines in FIGS. 5(a) to 5(g) indicate mask aperture portions for ion implantation. However, FIGS. 5(a) to 5(g) all illustratively show rough positions of the mask aperture portions, and do not faithfully show actual mask alignment.

The mask patterns shown in FIGS. 5(a) and 5(b) are patterns for amorphizing the entirety of the i layer 22. Note that according to the mask pattern shown in FIG. 5(a), the entirety of the photodiode 7 is amorphized, including a channel region 21c of the p layer 21 and a channel region 23c of the n layer 23. According to the mask pattern shown in FIG. 5(b), a region including the entirety of the i layer 22, the junction between the p layer 21 and the i layer 22, and the junction between the i layer 22 and the p layer 23 is amorphized. However, with the structure shown in FIG. 5(b), the channel region 21c of the p layer 21 and the channel region 23c of the n layer 23 are not amorphized. Note that in the case of the mask pattern shown in FIG. 5(a), there is the advantage that the photolithography mask for performing the patterning of this ion implantation mask can also be used as the photolithography mask for the light shielding film 8.

Also, according to the mask pattern shown in FIG. 5(c), a region of the i layer 22 excluding the junction with the p layer 21 and the junction with the n layer 23 is amorphized. Furthermore, according to the mask pattern shown in FIG. 5(d), a region of the i layer 22 excluding the junction with the p layer 21 and including the junction with the n layer 23 is amorphized. According to the mask pattern shown in FIG. 5(e), a region of the i layer 22 including the junction with the p layer 21 and excluding the junction with the n layer 23 is amorphized. In this way, with a structure in which at least either the junction on the p layer 21 side or the n layer 23 side is not formed into amorphous silicon, there is the advantage that performance as a photosensor is not impaired since the PN junction at that junction does not break down. Also, a comparison of the mask pattern shown in FIG. 5(c) and the mask patterns shown in FIGS. 5(d) and 5(e) shows that the mask patterns shown in FIGS. 5(d) and 5(e) have the advantage that alignment is easier than with the mask pattern shown in FIG. 5(c).

Note that although the entire range in the length direction (direction parallel to the junction) of the i layer 22 can be amorphized with the mask patterns shown in FIGS. 5(a) to 5(e), the entire range in the length direction of the i layer 22 does not necessarily need to be amorphized. Specifically, as shown in FIG. 5(f), a structure is possible in which only the center portion of the i layer 22 is amorphized. As another example, as shown in FIG. 5(g), even if the aperture portion A of the mask crosses either of the two edges that are parallel to the direction perpendicular to the p layer/i layer junction and the n layer/i layer junction of the photodiode 7, the necessary effect can be achieved as long as at least part of the i layer 22 is amorphized.

Note that Si ions may be used in place of Ar ions when amorphizing the i layer 22. Also, the ion implantation for amorphization may be performed at any timing from when the crystallization of the silicon films 14, 33, and 34 ends until when the third interlayer insulating film 28 is formed. However, in the case of performing ion implantation after the formation of the second interlayer insulating film 27, it is effective to set a high accelerating voltage for ion implantation and increase the implantation dose amount.

Next, as shown in FIG. 6(a), the second interlayer insulating film 27 is formed such that the silicon films 14, 33, and 34 are covered. The second interlayer insulating film 27 functions as a TFT gate insulating film as well.

The second interlayer insulating film 27 can also be formed by, for example, forming a silicon oxide film or silicon nitride film by a CVD method, similarly to the case of the first interlayer insulating film 26. Specifically, in the case of forming a silicon oxide film, it is sufficient to implement a plasma CVD method using SiH₄ and N₂O (or O₂) as the source gases. Also, the second interlayer insulating film 27 may also be a single-layer film or multi-layer film, similarly to the first interlayer insulating film 26. The thickness of the second interlayer insulating film 27 is set to, for example, 10 nm to 120 nm.

Next, as shown in FIG. 6(b), the gate electrode 18 of the pixel driving TFT 6 and a gate electrode 35 of the peripheral circuit TFT are formed. Specifically, first a conductive layer is formed by implementing a sputtering method, a vacuum deposition method, or the like with use of a metal material having an element such as Ta, Ti, W, Mo, or Al as a main component. As one example, a W/TaN alloy conductive layer is formed in the present embodiment. Next, a resist pattern is formed on a portion of the conductive layer that overlaps the gate electrode formation region with use of photolithography, and etching is performed using this resist pattern as a mask, thus forming the gate electrodes 18 and 35.

Next, as shown in FIG. 6(c), ion implantation for forming a p-type diffusion layer is performed. In the present embodiment, a p-type diffusion layer is formed in the photodiode 7 (see FIGS. 1 and 2) and the peripheral circuit TFT. Specifically, a resist pattern 36 is first formed as shown in FIG. 6(c). The resist pattern 36 includes an aperture in a portion that overlaps the formation region for the p layer 21 (see FIG. 2) of the photodiode 7, and in a portion that overlaps a source region 37 and a drain region 38 of the peripheral circuit TFT. 40 indicates a channel region of the peripheral circuit TFT.

Subsequently, ion implantation is performed with use of a p-type impurity such as boron (B) or indium (In), using settings such as an implantation energy of 10 [KeV] to 80 [KeV] and a dose amount of 5×10¹⁴ [ions] to 2×10¹⁶ [ions]. At this time, the impurity concentration after implantation is preferably 1.5×10²⁰ to 3×10²¹ [atoms/cm3]. After the ion implantation has ended, the resist pattern 36 is eliminated.

Next, as shown in FIG. 7(a), ion implantation for forming an n-type diffusion layer is performed. In the present embodiment, an n-type diffusion layer is formed in the photodiode 7 and the pixel driving TFT 6. Specifically, a resist pattern 39 is first formed as shown in FIG. 7(a). The resist pattern 39 includes an aperture in a portion that overlaps the formation region for the n layer 23 (see FIG. 2) of the photodiode 7, and in a portion that overlaps the source region 15 and the drain region 17 of the pixel driving TFT 6.

Subsequently, ion implantation is performed with use of an n-type impurity such as phosphorous (P) or arsenic (As), using settings such as an implantation energy of 10 [KeV] to 100 [KeV] and a dose amount of 5×10¹⁴ [ions] to 1×10¹⁶ [ions]. At this time as well, the impurity concentration after implantation is preferably 1.5×10²⁰ to 3×10²¹ [atoms/cm3]. After the ion implantation has ended, the resist pattern 39 is eliminated.

Also, although not shown, ions can be implanted in the i layer 22 of the photodiode 7 as well in the present embodiment. This ion implantation is performed such that the i layer 22 is closer to being electrically neutral than the p layer 21 and the n layer 23. Also, the implantation of ions in the i layer 22 may be performed by using either of the cases where the above-described ion implantation shown in FIGS. 6(c) and 7(a) is divided into multiple instances, or by ion implantation that is separate from these cases.

Furthermore, in the present embodiment, heat treatment is performed after the ion implantation has ended in order to activate the impurities. The heat treatment in this case can be performed by, for example, a furnace annealing method, a laser annealing method, or a rapid thermal annealing method. Specifically, in the case of performing heat treatment by a furnace annealing method, the heat treatment is performed in a nitrogen atmosphere with the temperature being set to 300° C. to 650° C., or preferably to 550° C., and the treatment time being set to approximately 4 hours.

Next, as shown in FIG. 7(b), the third interlayer insulating film 28 is formed such that the second interlayer insulating film 27 and the gate electrodes 18 and 35 are covered. The third interlayer insulating film 28 can also be formed by forming a silicon oxide film or silicon nitride film by a CVD method, similarly to the case of the first interlayer insulating film 26. Also, third second interlayer insulating film 28 may also be a single-layer film or multi-layer film, similarly to the first interlayer insulating film 26. The thickness of the third interlayer insulating film 28 is set to, for example, 200 nm to 2,000 nm, or preferably to 1 μm.

Next, as shown in FIG. 7(c), after a contact hole penetrating the second interlayer insulating film 27 and the third interlayer insulating film 28 (or only the third interlayer insulating film) has been formed, the source wiring 19a, the drain wiring 19b, and the gate wiring 20 that are to be connected to the pixel driving TFT 6 are formed. At the same time, the wiring 24 and the wiring 25 that are to be connected to the photodiode 7 are formed, and wiring 41 and wiring 42 that are to be connected to the peripheral circuit TFT are formed.

Also, the wiring are each formed by filling the contact holes with a conductive material, then forming a conductive film on the third interlayer insulating film 28, and furthermore forming a resist pattern and performing etching. In the present embodiment, the conductive film for wiring is a stacked film obtained by forming a Ti film (thickness of 200 nm), an aluminum film (thickness of 600 nm) containing Ti, and a Ti film (thickness of 100 nm) in the stated order using a sputter method.

Thereafter, the protective film 43 is formed so as to cover the source wiring 19a, the drain wiring 19b, the gate wiring 20, the wiring 24, 25, 41, and 42, and furthermore the third interlayer insulating film 28. The protective film 43 can be formed by forming an organic film by an application method or the like. Also, the protective film 43 may also be either a single-layer film or a multi-layer film. The thickness of the protective film is set to, for example, 1 μm to 5 μm, or preferably 2 μm to 3 μm.

After a contact hole that penetrates the protective film 43 has been formed, the pixel electrode 9 is formed. The pixel electrode 9 is formed by forming an ITO film by a CVD method, forming a resist pattern, and then performing etching.

Also, although the silicon films of the pixel driving TFT 6, the peripheral circuit TFT, and the photodiode 7 are formed using continuous grain silicon in the present embodiment as described above, there is no limitation to this. Since polycrystalline silicon also has properties similar to those of continuous grain silicon, polycrystalline silicon may be used to form the pixel driving TFT 6, the peripheral circuit TFT, and the photodiode 7 of the present embodiment.

In the case of using polycrystalline silicon, a silicon film 32 made of polycrystalline silicon is formed in the step shown in FIG. 4(c). The silicon film 32 made of polycrystalline silicon can be formed as follows, for example. Firstly, a silicon film made of amorphous silicon is formed. Then, the silicon film made of amorphous silicon is dehydrogenated by being heated for 2 hours at 500° C., for example, then annealed so as to crystallize. One example of the annealing method is a known laser annealing method. One specific example is a method of irradiating the amorphous silicon film with a laser beam from an excimer laser.

Also, polycrystalline silicon with a further enlarged crystal grain size can be used by using an SLS (Sequential Lateral Solidification) method, a CLC (CW-laser Lateral Crystallization) method, a SELAX (Selectively Enlarging Laser X'tallization) method, or the like. The SLS method is a method in which, when performing irradiation with the excimer laser to form the polycrystalline silicon film, the crystal grains are enlarged in the laser scanning direction by reducing the pitch in the scanning direction. The CLC method is a method in which the crystal grains are enlarged in the laser scanning direction by using a continuous oscillation laser. The SELAX method is a method in which the crystal grains are enlarged in the laser scanning direction by causing crystallization with use of an excimer laser, and thereafter using a continuous oscillation laser.

### INDUSTRIAL APPLICABILITY

The present invention is industrially applicable as a photodiode for a display device and a display device including a photodiode.

### REFERENCE SIGNS LIST

1 liquid crystal display panel
2 active matrix substrate
3 liquid crystal layer
4 filter substrate
5 glass substrate (base substrate of active matrix substrate)
6 active element (pixel driving TFT)
7 photodiode
8 light shielding film
9 pixel electrode
10 glass substrate (base substrate of filter substrate)
11a, 11b, 11c color filter
12 common electrode
13 backlight
14 silicon film configuring active element
15 source region
16 channel region
17 drain region
18 gate electrode
19a source wiring
19b gate wiring
20 gate wiring
21 p layer
22 i layer
23 n layer
24, 25 photodiode wiring
26 first interlayer insulating film
27 second interlayer insulating film
28 third interlayer insulating film
29 illumination light
30 silicon film to be light shielding film
31 resist pattern
32 silicon film to be TFT and photodiode
33 silicon film configuring photodiode
34 silicon film configuring peripheral circuit TFT
35 gate electrode of peripheral circuit TFT
36 resist pattern
37 source region of peripheral circuit TFT
38 drain region of peripheral circuit TFT
39 resist pattern
40 channel region of peripheral circuit TFT
41, 42 peripheral circuit TFT wiring
43 protective film

1. A photodiode formed in a polycrystalline silicon layer or a continuous grain silicon layer on a substrate of a display device, the photodiode comprising:
a semiconductor region of a first conductivity-type, an intrinsic semiconductor region, and a semiconductor region of a second conductivity-type that is opposite from the first conductivity-type,
wherein at least a portion of the intrinsic semiconductor region is amorphous silicon.

2. The photodiode according to claim 1, wherein the entirety of the intrinsic semiconductor region, as well as the first conductivity-type semiconductor region and the second conductivity-type semiconductor region are amorphous silicon.

3. The photodiode according to claim 1, wherein the entirety of the intrinsic semiconductor region, a junction portion of the intrinsic semiconductor region and the first conductivity-type semiconductor region, and a junction portion of the intrinsic semiconductor region and the second conductivity-type semiconductor region are amorphous silicon.

4. The photodiode according to claim 1, wherein in the intrinsic semiconductor region, a region excluding at least one of a junction portion with the first conductivity-type semiconductor region, and a junction portion with the second conductivity-type semiconductor region is amorphous silicon.

5. A display device comprising the photodiode according to claim 1.

6. The display device according to claim 5
wherein the substrate is an active matrix substrate having a plurality of active elements arranged in a matrix, and
a plurality of the photodiodes are formed on the active matrix substrate.

7. A manufacturing method for a photodiode comprising the steps of:
forming a polycrystalline silicon layer or a continuous grain silicon layer on a substrate of a display device;
causing amorphization of at least a portion of a region to be an intrinsic semiconductor region of the photodiode in the silicon layer by ion implantation; and
forming a semiconductor region of a first conductivity-type of the photodiode, and a semiconductor region of a second conductivity-type that is opposite from the first conductivity-type, in the silicon layer.

8. The manufacturing method for a photodiode according to claim 7, wherein argon ions or silicon ions are used in the ion implantation step.

9. The manufacturing method for a photodiode according to claim 7, wherein in the ion implantation step, ion implantation is performed on the entirety of the region to be the intrinsic semiconductor region, as well as on a region to be the first conductivity-type semiconductor region and a region to be the second conductivity-type semiconductor region, in the silicon layer.

10. The manufacturing method for a photodiode according to claim 7, wherein in the ion implantation step, ion implantation is performed on the entirety of the region to be the intrinsic semiconductor region, a region to be a junction portion of the intrinsic semiconductor region and the first conductivity-type semiconductor region, and a region to be a junction portion of the intrinsic semiconductor region and the second conductivity-type semiconductor region, in the silicon layer.

11. The manufacturing method for a photodiode according to claim 7, wherein in the ion implantation step, ion implantation is performed on, within the region to be the intrinsic semiconductor region, a region excluding at least one of a region to be a junction portion with the first conductivity-type semiconductor region, and a region to be a junction portion with the second conductivity-type semiconductor region, in the silicon layer.
